(19) United States
(12) Patent Application Publication
(10) Pub. No.: US 2010/0080074 A1
(43) Pub. Date: Apr. 1, 2010

(54) SEMICONDUCTOR MEMORY DEVICE

(75) Inventors: Takuro OHMARU, Atsugi (JP); Tomoaki ATSUMI, Isehara (JP); Toshihiko SAITO, Atsugi (JP)

Correspondence Address: ERIC ROBINSON, PMB 955, 21010 SOUTHBANK ST., POTOMAC FALLS, VA, 20165, US

(73) Assignee: SEMICONDUCTOR ENERGY LABORATORY CO., LTD., Atsugi (JP)

(21) Appl. No.: 12/567,975

(22) Filed: Sep. 28, 2009

(30) Foreign Application Priority Data
Sep. 30, 2008 (JP) 2008-254100

(51) Int. Cl. G11C 29/00

(52) U.S. Cl. 365/200

(57) ABSTRACT

Easy and fast memory access with correcting defects is to be realized. In a spare memory in a semiconductor memory device, a redundant memory cell array that stores the number of correcting defects is provided. When a signal from the outside is received, the signal is switched to the redundant memory cell array, and the number of correcting defects is judged. Then, based on the result of the judgment, it is determined the judgment of a defective memory cell is continued or the judgment is finished to write data to a main memory cell. By providing the redundant memory cell array that stores the number of correcting defects, a state of correcting defects can be observed fast in such a manner.

### TECHNICAL FIELD

The technical field relates to a defect correcting technology in a semiconductor memory device.

### BACKGROUND ART

In recent years, the yield of memory cells tends to decrease due to an increase and a complexity of manufacturing steps with an increase in the capacity of a semiconductor memory device. Thus, various kinds of a defect correcting technology for a memory cell array including a defective memory cell in order to improve the yield of a semiconductor memory device itself has been suggested.

For example, a technology for correcting a defect, by replacing a memory cell which is determined to be defective by a redundant circuit provided in the semiconductor memory device with a spare cell has been suggested (for example, see Patent Document 1).

In addition, a technology for correcting a defect by replacing a defect generated in a DRAM (dynamic random access memory) in a semiconductor memory device with a RAM portion for redundancy in a LSI for correcting defects installed in the semiconductor memory device has been suggested (for example, see Patent Document 2).

### REFERENCE

[Patent Document 1] Japanese Published Patent Application No. 2006-107583
[Patent Document 2] Japanese Published Patent Application No. H8-16486

### DISCLOSURE OF INVENTION

However, since detecting addresses of a defective memory cell and an unused spare memory is needed to correct a defect, the number of access to a memory is increased with an increase of a memory capacity and it makes time for access to the memory longer. Further, a structure of a control circuit is enlarged with an increase of the memory capacity.

In view of the above problems, it is an object to realize easy and fast access to a memory without enlargement of a structure of a control circuit.

An embodiment of the present invention is a semiconductor memory device provided with a redundant memory cell array which stores the number of correcting defects in a spare memory. When a signal is received from the outside, the signal is switched to the redundant memory cell array, and the number of correcting defects is judged. Then, based on the result of the judgment, the judgment of a defective memory cell is continued or the judgment is finished to write data to a main memory cell.

One embodiment is a semiconductor memory device including a first memory cell array including a plurality of memory cell capable of electrical writing and reading, a second memory cell array including a plurality of a redundant memory cell, and a control circuit; the second memory cell array having a first region including a redundant memory cell which stores the number of correcting writing defects and a second region including a redundant memory cell which stores an address of a defective memory cell.

Here, the control circuit accesses the first region, to judge the number of correcting defects, and determines whether to access the second region or not depending on a result of the judgment.

The second memory cell array may have a third region including a redundant memory cell which replaces a defective memory cell.

This semiconductor memory device may include a memory cell which stores normal writing.

The semiconductor memory device can be applied to a DRAM, an SRAM, a mask ROM, a PROM, an EPROM, an EEPROM, a flash memory, and the like.

In the semiconductor memory device, an address of a defective memory cell is judged in accordance with the number of correcting defects. Therefore, easier and faster operation can be realized. In addition, the operation can be applied to a high-capacity memory.

Further, the reliability of a semiconductor memory device can be evaluated by monitoring the number of correcting defects.

### BRIEF DESCRIPTION OF DRAWINGS

In the accompanying drawings;

FIG. 1 is a block diagram illustrating a structure of a semiconductor memory device;

FIG. 2 is a flow chart illustrating procedures when a controlling process of a redundant memory is executed;

FIG. 3 is a flow chart illustrating procedures when a controlling process of a redundant memory is executed;

FIG. 4 is a memory map diagram of a memory cell array;

FIG. 5 is a memory map diagram of a memory cell array;

FIG. 6 is a memory map diagram of a memory cell array;

FIG. 7 is a memory map diagram of a memory cell array;

FIG. 8 is a memory map diagram of a memory cell array;

FIG. 9 is a memory map diagram of a memory cell array;

FIG. 10 is a memory map diagram of a memory cell array;

FIG. 11 is a block diagram illustrating a structure of a semiconductor device;

FIG. 12 illustrates an example of a mask layout of a semiconductor memory device; and

FIG. 13 is a circuit diagram of memory cell of a semiconductor memory device.

### BEST MODE FOR CARRYING OUT THE INVENTION

Embodiments of the invention disclosed hereinafter with reference to the drawings. Note that the invention is not limited to the following description, and those skilled in the art can easily understand that modes and details of the invention can be changed in various ways without departing from the purpose and the scope of the invention. Therefore, it should be noted that the present invention should not be interpreted as being limited to the following description of the embodiments.

### Embodiment 1

In this embodiment, an example of a semiconductor memory device and a technology for correcting defects in the semiconductor memory device will be described.

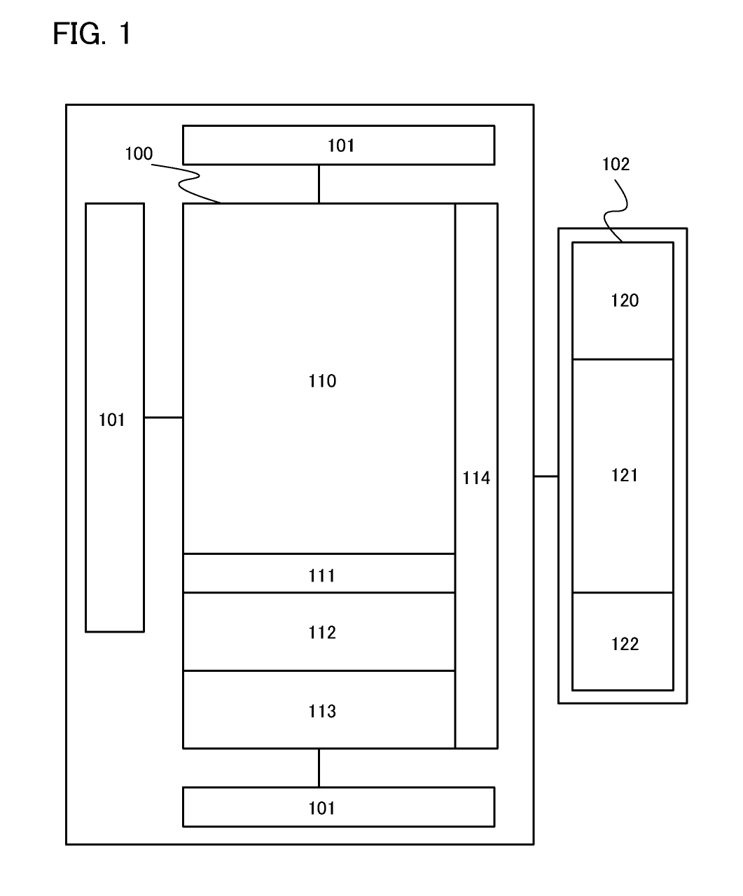

First, an example of a structure of a semiconductor memory device will be described with reference to FIG. 1. Here, FIG. 1 is a circuit block diagram of the semiconductor memory device according to this embodiment. As shown in FIG. 1, the semiconductor memory device includes a memory cell array 100, and a reading driver 101 and a redundant control circuit portion 102 which are around the main memory cell array 100.

The memory cell array 100 includes a main memory cell 110, a spare memory cell, and a memory cell 114 for preventing additional writing. Note that the spare memory cell is provided with a memory cell 111 for a redundant function, a memory cell 112 for redundant judgment, and a memory cell 113 for replacement.

Input data is written in the main memory cell 110 and the memory cell 113 for replacement. The memory cell 111 for a redundant function stores the number of correcting defects. The memory cell 112 for redundant judgment stores an address of a defective memory cell and an access-forbidden address. The memory cell 114 for preventing additional writing stores normal writing of input data to the main memory cell 110 or the memory cell 113 for replacement.

A memory cell of the spare memory and the memory cell 114 for preventing additional writing include a nonvolatile memory which retains stored data even when the power is turned off. Note that a memory which is a kind of nonvolatile memory and has a plurality of memory cells that can be written only once is preferable from an aspect of security because data in the nonvolatile memory is difficult to be falsified.

The redundant control circuit portion 102 includes a redundancy controlling circuit 120, a redundancy comparator circuit 121, and a redundancy latch circuit 122.

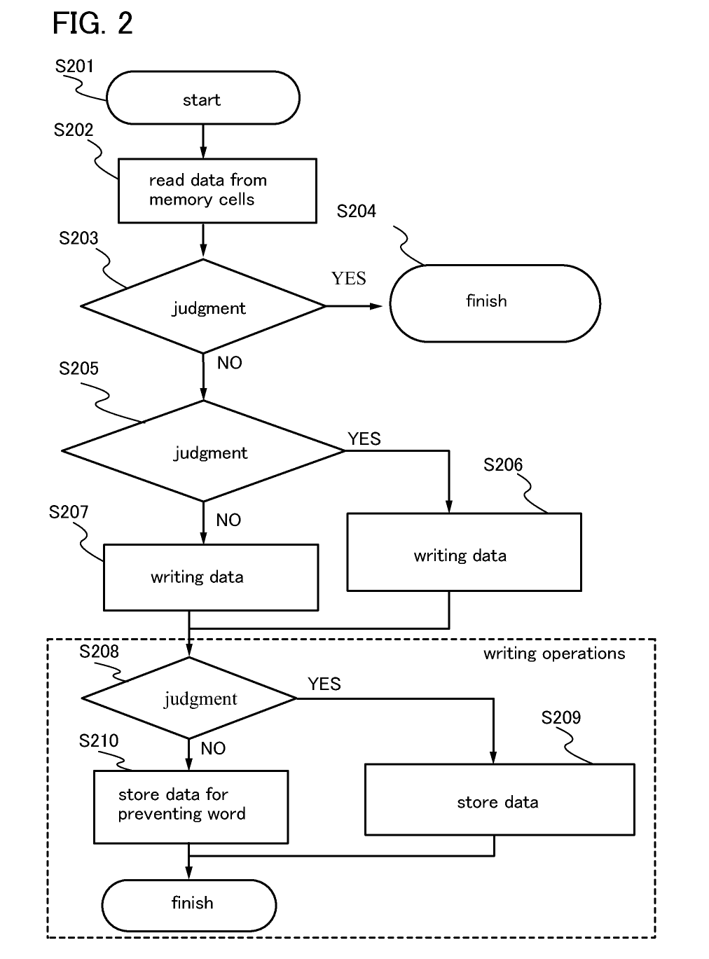

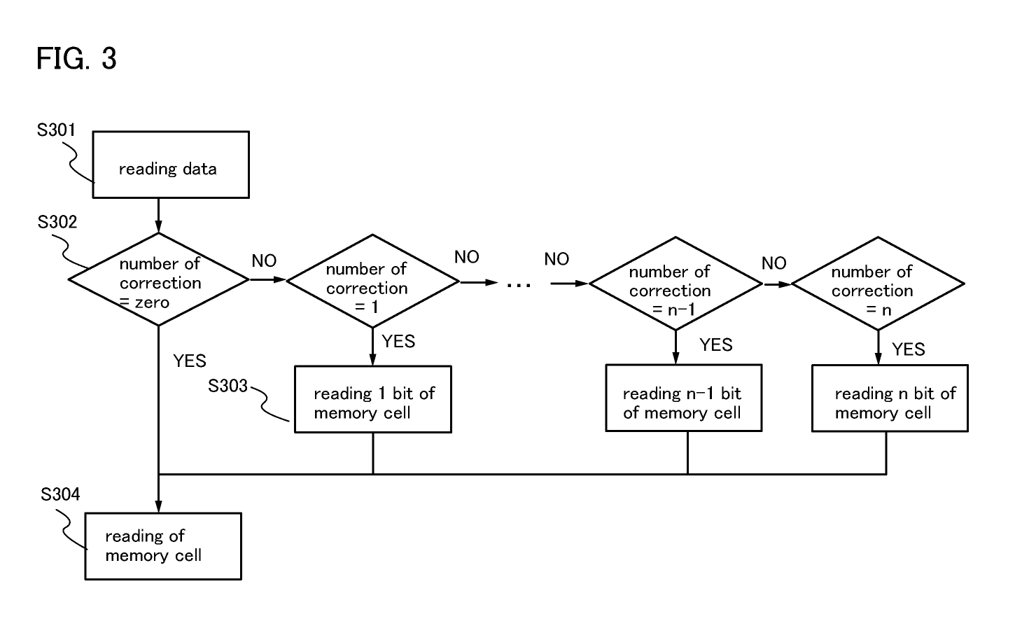

Subsequently, an example of writing operation of the semiconductor memory device will be described with reference to FIGS. 2 and 3. Here, FIG. 2 is a flow chart illustrating procedures when a controlling process of a redundant memory is executed. In FIG. 2, the reference numeral following “S” illustrates each step in the flow chart.

In Step S201, the controlling process of a redundant memory starts when a memory access start signal is received from the outside. First, a signal is switched from the main memory cell 110 to the memory cell 111 for a redundant function by the redundancy controlling circuit 120.

In Step S202, the data which is stored in the memory cell 111 for a redundant function, the memory cell 112 for redundant judgment, and the memory cell 114 for preventing additional writing is read. Processes in Step S202 are described with reference to FIG. 3.

FIG. 3 is a flow chart illustrating a procedure when Step S202 in FIG. 2 is executed if the maximum correcting number is n. In FIG. 3, the reference numeral following “S” illustrates each step in the flow chart.

In Step S301, the memory cell 111 for a redundant function is read and an address and data of the memory cell is kept in a register in the redundancy latch circuit 122.

Then, when an address signal is received from outside, an access word of the main memory cell 110 is specified. After that, a signal is switched from the main memory cell 110 to the memory cell 112 for redundant judgment by the redundancy controlling circuit 120.

In Step S302, the number of correcting defects is judged by the data read from the memory cell 111 for a redundant function. The process proceeds to Step S304 when there is no memory cell stored data in the memory cell 111 for a redundant function; that is, when the number of correcting defects is zero. On the other hand, the process proceeds to Step S303 when there is one or more memory cells stored data in the memory cell 111 for a redundant function, that is, when the number of correcting defects is one or more.

In Step 303, the number of bit addresses corresponding to the access word of the memory cell 112 for redundant judgment (hereinafter such a bit address is referred to as a “corresponding bit address” as appropriate) is read as many as the number of bits corresponding to the number of correcting defects. Then, the address and data of the memory cell are kept in the register in the redundancy latch circuit 122. This Step S303 is referred to as a judgment for a defective word address.

In step S304, the memory cell 114 for preventing additional writing corresponding to the access word is read. Then, the address and data of the memory cell are kept in the register in the redundancy latch circuit 122. This Step S304 is referred to a judgment for preventing additional writing.

Next, in Step S203 to S207 in FIG. 2, the results of the judgment of the number of correcting defects, the judgment of a defective word address, and the judgment for preventing additional writing which are kept in the register in the redundancy latch circuit 122 are read. Then, a state of the circuit is determined.

First, in Step S203, whether the memory cell 114 for preventing additional writing corresponding to the access word stores data or not is judged. When the memory cell 114 for preventing additional writing corresponding to the access word stores data, in other words, when the access word is an additional writing prevention word, the process proceeds to Step S204, and a controlling process of redundant memory is finished. On the other hand, when the access word is not an additional writing prevention word, the process proceeds to Step S205.

In Step S205, whether the corresponding bit address of the memory cell 112 for redundant judgment stores data or not is judged. When data is stored, the process proceeds to Step S206. On the other hand, when data is not stored, the process proceeds to Step S207.

Note that the data stored in the corresponding bit address of the memory cell 112 for redundant judgment means that a defect in an access word is corrected and word address of the memory cell 113 for replacement is allocated to an access word.

In Step S206, an address signal is transmitted to the memory cell 113 for replacement and data writing is executed.

On the other hand, in Step S207, an address signal is transmitted to the main memory cell 110 and data writing is executed.

In Step S208, the data is read from a memory cell immediately after writing data and the comparison between the read data and the expected value is executed in the redundancy comparator circuit 121. As the result of the comparison between the read data and the expected value, the process proceeds to Step S209 when the data does not match the expected value, that is, a defective memory is detected. On the other hand, the process proceeds to Step S210 when a defective memory is not detected.

In Step S209, data is stored in the memory cell 111 for a redundant function corresponding to the number of correcting defects. Note that, when the entire memory cell 111 for a redundant function stores data, the data is not stored.

Subsequently, data is stored in a bit address corresponding to a word address where a defect occurs of the memory cell 112 for redundant judgment. Note that, if the entire memory cell 111 for a redundant function already stores data, the data is stored in a final word of the memory cell 112 for redundant judgment (hereinafter the final word is referred to as an “access-forbidden memory cell”). Thus, a series of writing operations is finished.

The memory cell 113 for replacement is prepared in order to correct a memory cell in which writing is failed. However, when the number of failure of writing is more than the number of words of the memory cell 113 for replacement, that is, when the memory cell 111 for a redundant function cannot store data because the entire memory cell 111 for a redundant function already stores data, correcting the memory cell is impossible. Since such a memory cell in which it is impossible to correct defects stores imperfect data, it is inappropriate to use the memory cell.

Therefore, if data is stored in an access-forbidden memory cell, access (writing and reading) to a memory cell having a word address of the main memory cell 110 corresponding to a bit address storing the data is forbidden afterwards.

On the other hand, in Step S210, the memory cell 114 for preventing additional writing is accessed and data that writing is normally completed is stored. Thus, a series of writing operations is finished.

As described above, in the writing operation of the semiconductor memory device, a defect is judged by access to each circuit of the spare memory after a memory access start signal is received from the outside. According to the result of the judgment, it is determined which memory cell is to be accessed: the main memory cell 110 or the memory cell 113 for replacement. Therefore, there is no need to access to the entire memory cell and easy and fast access the memory cell is possible even if the capacity of the memory cell is increased.

In the semiconductor memory device, a memory access start signal is received from the outside, and after that, the number of correcting defects is read. When the number of correcting defects is zero, faster operation can be realized because there is no need to access the memory cell 112 for redundant judgment in the subsequent judgment for defects. When the number of correcting defects is one or more, the corresponding bit address as many as the number of bits corresponding to the number of correcting defects may be read. In addition, if the number of correcting defects achieves the upper limit, failure of writing can be prevented by switching the memory access start signal to another device, and the like.

In addition, the reliability of the semiconductor memory device can be evaluated by monitoring the number of correcting defects.

Further, in the semiconductor memory device, only access to the memory cell 111 for a redundant function and the corresponding bit address of the memory cell 112 for redundant judgment is necessary in order to obtain a state of defect correction. Therefore, a state of defect correction can be observed faster than the case of accessing the entire memory cell 112 for redundant judgment

Furthermore, in the semiconductor memory device, the memory cell in which writing is normally completed is protected while access (writing and reading) to the memory cell in which it is impossible to correct a defect is forbidden. Accordingly, the reliability of the semiconductor memory device can be improved.

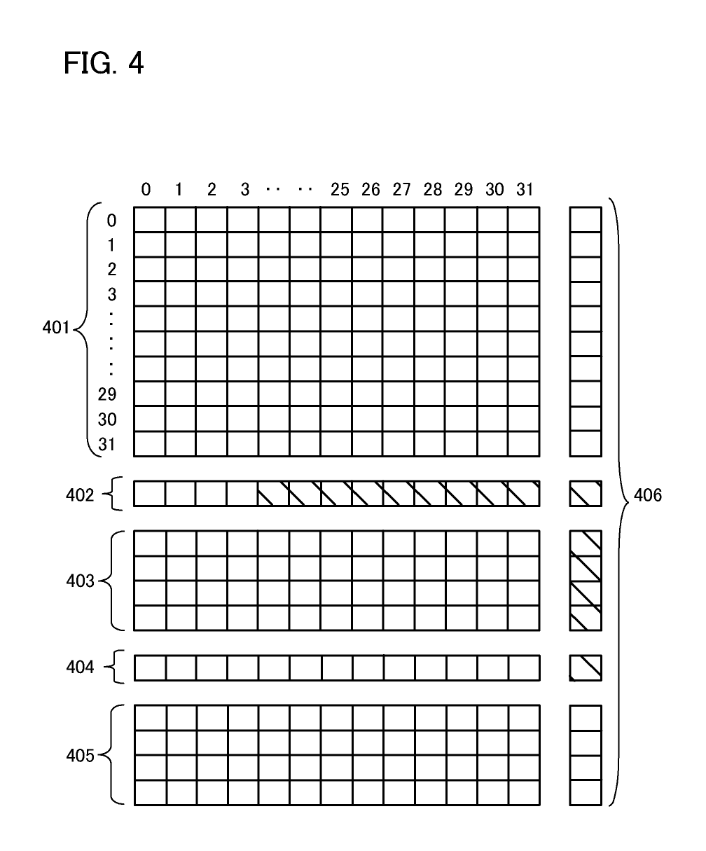

Then, specific examples of a technology for correcting defects in the semiconductor memory device will be described with reference to the following cases (1) to (8) and FIG. 4 to FIG. 8.

FIG. 4 illustrates an example of a memory map of the memory cell array 100 in FIG. 1. The memory cell array in FIG. 4 is provided with a main memory cell 401 having a size of 32×32, a memory cell 402 for redundant function having a size of 1×4, a memory cell 403 for redundant judgment having a size of 4×32, an access-forbidden memory cell 404 having a size of 1×32, a memory cell 405 for replacement having a size of 4×32, and a memory cell for preventing additional writing 406 having a size of 36×1.

First, description is made on the case (1) where writing on a twenty-fifth bit is failed after a third word is specified by an address signal. Note that FIG. 4 is a memory map when the address signal is received.

As described above, when the semiconductor memory device receives a signal from the outside, the judgment of the number of correcting defects, the judgment of a defective word address, and the judgment of preventing additional writing are executed.

In FIG. 4, (i) when the memory cell 402 for redundant function is read, data is not stored. Therefore, the result of the judgment is that the number of correcting defects is zero in advance, and the result of the judgment is kept in a register.

Next, (ii) when a third bit that is the corresponding bit address of the memory cell 403 for redundant judgment is read, data is not stored. Therefore, the result of the judgment is that correcting a defect is not executed to the third word of the main memory cell 401, and the result of the judgment is kept in the register.

Next, (iii) when the third bit that is the corresponding bit address of the access-forbidden memory cell 404 is read, data is not stored. Therefore, the result of the judgment is that access (writing and reading) to the third word is possible, and the result of the judgment is kept in the register.

Note that, since the result of the judgment is that the number of correcting defects is zero in advance, the judgment (ii) of a defective word address is not necessary.

Finally, (iv) when the memory cell for preventing additional writing 406 in the third word of the main memory cell 401 is read, data is not stored. Therefore, the result of the judgment is that writing operation can be executed to the third word in the main memory cell 401, and the result of the judgment is kept in the register.

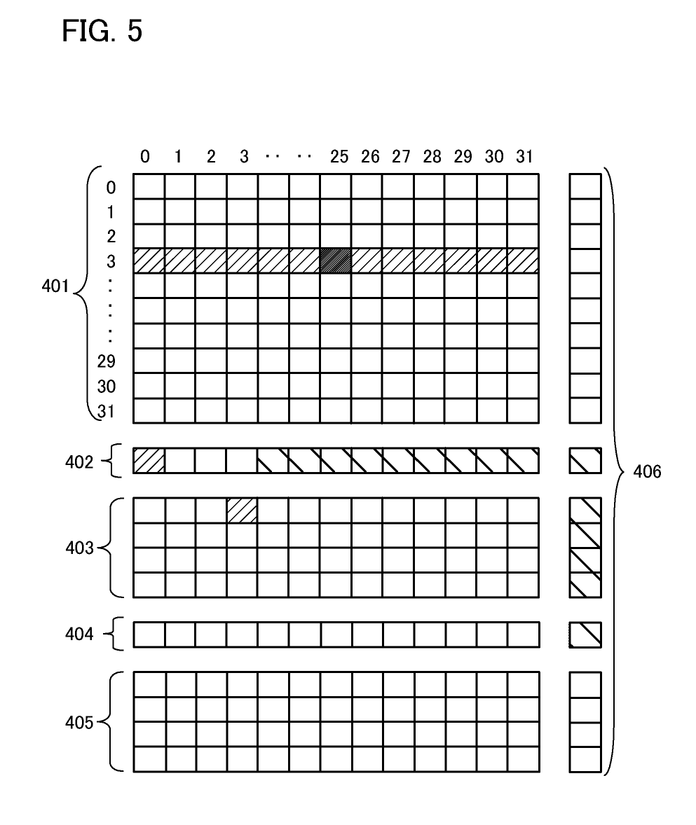

According to the result of the judgment (i) to (iv), an address signal is transmitted to a third word of the main memory cell 401 to execute writing data is decided. After that, data is written (see the main memory cell 401 in FIG. 5).

When the data is read from the memory cell and the comparison between the read data and the expected value is executed immediately after writing data, the result of the comparison shows that the data does not match the expected value because writing is failed at the twenty-fifth bit.

Accordingly, the data is stored in a zeroth bit in the memory cell 402 for redundant function and the third bit that is the corresponding bit address of a zeroth word in the memory cell 403 for redundant judgment (see the memory cell 402 for redundant function and the memory cell 403 for redundant judgment in FIG. 5). Note that the data has a function of allocating the zeroth word in the memory cell 405 for replacement in order to correct a defect of the third word.

Next, description is made on the case (2) where writing on the third bit is failed after the third word is specified by an address signal. Note that, FIG. 5 is a memory map when the address signal is received.

In FIG. 5, (i) when the memory cell 402 for redundant function is read, data is stored in the zeroth bit. Therefore, the result of the judgment is that the number of correcting defects is one, and the result of the judgment is kept in the register.

Next, (ii) when the third bit that is the corresponding bit address of the memory cell 403 for redundant judgment is read, data is stored in the zeroth bit. Therefore, the result of the judgment is that the zeroth word of the memory cell 405 for replacement is allocated for the correcting a defect in the third word, and the result of the judgment is kept in the register.

Next, (iii) when the third bit that is the corresponding bit address of the access-forbidden memory cell 404 is read, data is not stored. Therefore, the result of the judgment is that access (writing and reading) to the third word of the main memory cell 401 is possible, and the result of the judgment is kept in the register.

Finally, (iv) when the memory cell for preventing additional writing 406 in the zeroth word of the memory cell 405 for replacement is read, data is not stored. Therefore, the result of the judgment is that writing operation is possible on the zeroth word in the memory cell 405 for replacement, and the result of the judgment is kept in the register.

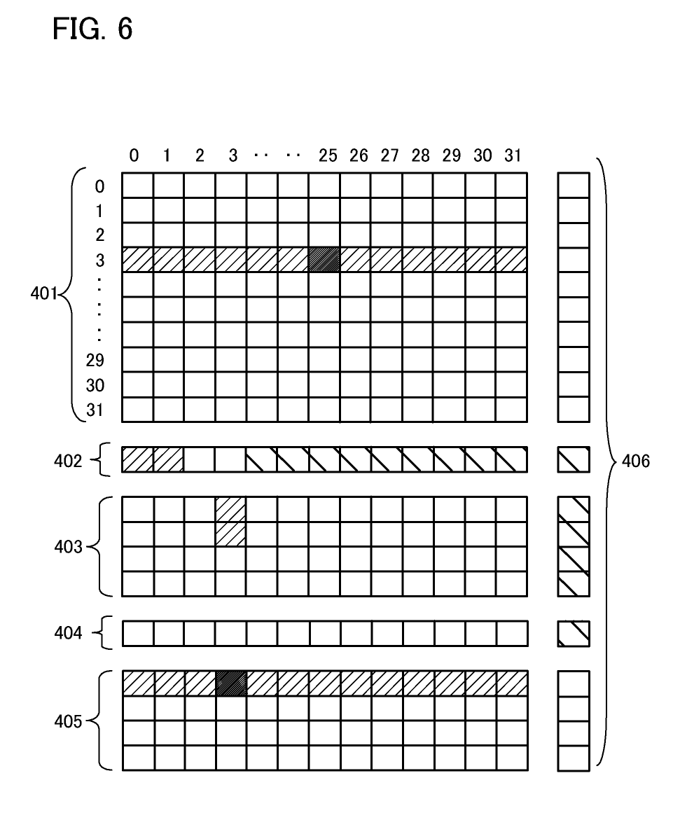

According to the above results of the judgment, it is determined that an address signal is transmitted to a zeroth word of the memory cell 405 for replacement in order to write data. After that, writing data is executed (see the memory cell 405 for replacement in FIG. 6).

When the data is read from the memory cell and the comparison between the read data and the expected value is executed immediately after writing data, the result of the comparison shows that the data does not match the expected value because writing is failed at the third bit.

Accordingly, the data is stored in a first bit of the memory cell 402 for redundant function and the third bit that is the corresponding bit address of a first word of the memory cell 403 for redundant judgment (see the memory cell 402 for redundant function and the memory cell 403 for redundant judgment in FIG. 6). Note that the data has a function of allocating the first word of the memory cell 405 for replacement for correcting a defect of the third word.

Next, description is made on the case (3) where writing on a twenty-sixth bit is failed after a twenty-ninth word is specified by an address signal. Note that FIG. 6 is a memory map when the address signal is received.

In FIG. 6, (i) when the memory cell 402 for redundant function is read, data is stored in the zeroth and first bits. Therefore, the result of the judgment is that the number of correcting defects is two, and the result of the judgment is kept in the register.

Next, (ii) when the twenty-ninth bit that is the corresponding bit address of the memory cell 403 for redundant judgment is read, data is not stored. Therefore, the result of the judgment is that the correcting a defect is not executed to the twenty-ninth word of the main memory cell 401, and the result of the judgment is kept in the register.

Next, (iii) when the twenty-ninth bit that is the corresponding bit address of the access-forbidden memory cell 404 is read, data is not stored. Therefore, the result of the judgment is that access (writing and reading) to the twenty-ninth word of the main memory cell 401 is possible, and the result of the judgment is kept in the register.

Finally, (iv) when the memory cell for preventing additional writing 406 in the twenty-ninth word of the main memory cell 401 is read, data is not stored. Therefore, the result of the judgment is that writing operation is possible on the twenty-ninth word of the main memory cell 401, and the result of the judgment is kept in the register.

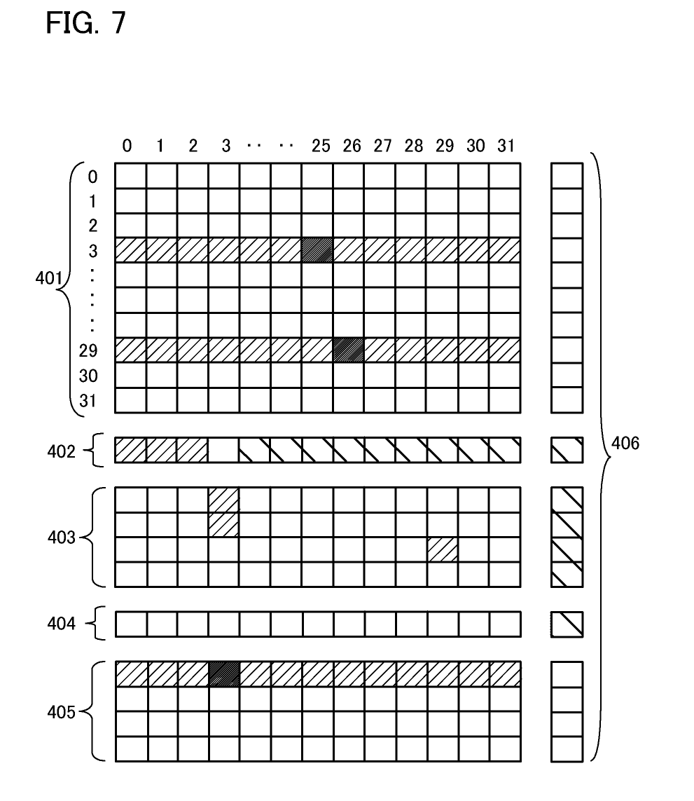

According to the above result of the judgment, it is determined that an address signal is transmitted to the twenty-ninth word of the main memory cell 401 in order to write data. After that, writing data is executed (see the main memory cell 401 in FIG. 7).

When the data is read from the memory cell and the comparison between the read data and the expected value is executed immediately after writing data, the result of the comparison shows that the data does not match the expected value because writing is failed at the twenty-sixth bit.

Accordingly, the data is stored in a second bit in the memory cell 402 for redundant function and the twenty-ninth bit that is the corresponding bit address in a second word of the memory cell 403 for redundant judgment (see the memory cell 402 for redundant function and the memory cell 403 for redundant judgment in FIG. 7). Note that the data has a function of allocating the second word of the memory cell 405 for replacement for correcting a defect of the twenty-ninth word.

Next, description is made on the case (4) where writing on a thirty-first bit is failed after the twenty-ninth word is specified by an address signal. Note that FIG. 7 is a memory map when the address signal is received.

In FIG. 7, (i) when the memory cell 402 for redundant function is read, data is stored in the zeroth, first, and a second bits. Therefore, the result of the judgment is that the number of correcting defects is three, and the result of the judgment is kept in the register.

Next, (ii) when the twenty-ninth bit that is the corresponding bit address of the memory cell 403 for redundant judgment is read, data is stored in the second word. Therefore, the result of the judgment is that the second word of the memory cell 405 for replacement be allocated for correcting a defect in the twenty-ninth word, and the result of the judgment is kept in the register.

Next, (iii) when the twenty-ninth bit that is the corresponding bit address of the access-forbidden memory cell 404 is read, data is not stored. Therefore, the result of the judgment is that access (writing and reading) to the twenty-ninth word in the main memory cell 401 is possible, and the result of the judgment is kept in the register.

Finally, (iv) when the memory cell for preventing additional writing 406 in the second word of the memory cell 405 for replacement is read, data is not stored. Therefore, the result of the judgment is that writing operation is possible on a second word of the memory cell 405 for replacement, and the result of the judgment is kept in the register.

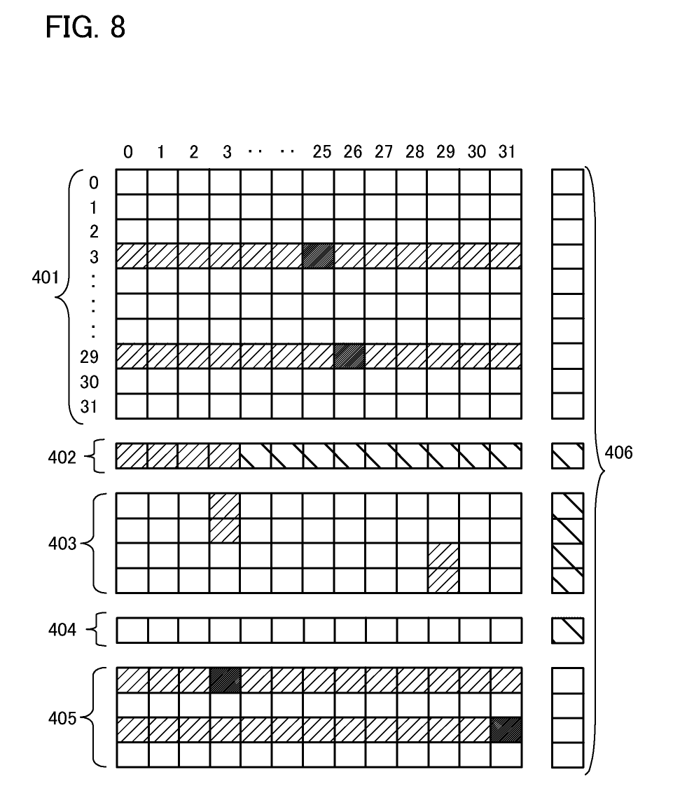

According to the above result of the judgment, it is determined that an address signal is transmitted to the second word in the memory cell 405 for replacement to write data. After that, writing data is executed (see the memory cell 405 for replacement in FIG. 8).

When the data is read from the memory cell and the comparison between the read data and the expected value is executed immediately after writing data, the result of the comparison shows that the data does not match the expected value because writing is failed at the thirty-first bit.

Accordingly, the data is stored in the third bit in the memory cell 402 for redundant function and the twenty-ninth bit that is the corresponding bit address of the third word in the memory cell 403 for redundant judgment (see the memory cell 402 for redundant function and the memory cell 403 for redundant judgment in FIG. 8). Note that the data has a function of allocating a third word of the memory cell 405 for replacement in order to correcting a defect of the twenty-ninth word.

Next, description is made on the case (5) where writing on the zeroth bit is failed after the first word is specified by an address signal. Note that FIG. 8 is a memory map when the address signal is received.

In FIG. 8, (i) when the memory cell 402 for redundant function is read, data is stored in the zeroth, first, second, and third bits. Therefore, the result of the judgment is that the number of correcting defects is four, and the result of the judgment is kept in the register.

Next, (ii) when the first bit that is the corresponding bit address of the memory cell 403 for redundant judgment is read, data is not stored. Therefore, the result of the judgment is that the correcting a defect is not executed to the first word of the main memory cell 401, and the result of the judgment is kept in the register.

Next, (iii) when the first bit that is the corresponding bit address of the access-forbidden memory cell 404 is read, data is not stored. Therefore, the result of the judgment is that access (writing and reading) to the first word of the main memory cell 401 is possible, and the result of the judgment is kept in the register.

Finally, (iv) when the memory cell for preventing additional writing 406 in the first word of the main memory cell 401 is read, data is not stored. Therefore, the result of the judgment is that writing operation can be executed to the first word in the main memory cell 401, and the result of the judgment is kept in the register.

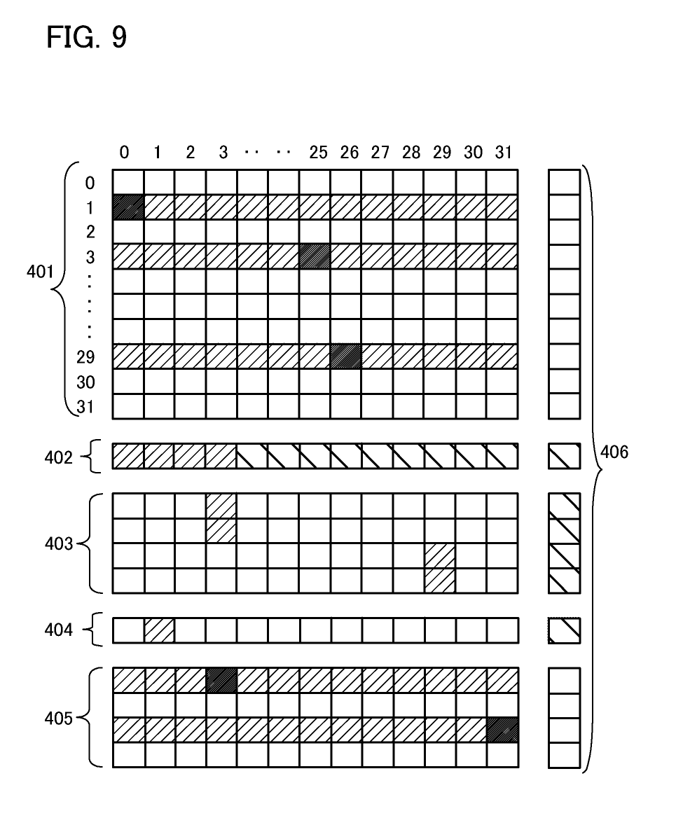

According to the result of the judgment of (i) to (iv), it is determined that an address signal is transmitted to the first word of the main memory cell 401 in order to write data. After that, writing data is executed (see the main memory cell 401 in FIG. 9).

When the data is read from the memory cell and the comparison between the read data and the expected value is executed immediately after writing data, the result of the comparison shows that the data does not match the expected value because writing is failed at the zeroth bit.

Since the zeroth, first, second, and third bits of the memory cell 402 for redundant function are fully used, a defect cannot be corrected anymore. In this case, the data is stored in the first bit that is the corresponding bit address of the access-forbidden memory cell 404 (see the access-forbidden memory cell 404 in FIG. 9). Accordingly, access (writing and reading) to the first word in the main memory cell is forbidden afterwards.

Next, description is made on the case (6) where the first word is specified by an address signal. Note that FIG. 9 is a memory map when the address signal is received.

In FIG. 9, the result of the judgment of (i), (ii), and (iv) is as the same as that in the case of (5) described above. Since only the result of the judgment of (iii) is different from that in the case of (5), the result of the judgment of (iii) will be described below.

(iii) When the first bit that is the corresponding bit address of the access-forbidden memory cell 404 is read, data is stored. Therefore, the result of the judgment is that access (writing and reading) to the first word is forbidden, and the result of the judgment is kept in the register.

According to the result of the judgment of (i) to (iv), since access (writing and reading) to the first word is forbidden, writing data is not executed and the operation is finished.

Next, description is made on the case (7) where the third word is specified by an address signal and writing is finished normally. Note that FIG. 9 is a memory map when the address signal is received.

In FIG. 9, (i) when the memory cell 402 for redundant function is read, data is stored in the zeroth, first, second, and third bits. Therefore, the result of the judgment is that the number of correcting defects is four, and the result of the judgment is kept in the register.

Next, (ii) when the third bit that is the corresponding bit address of the memory cell 403 for redundant judgment is read, data is stored in the first word. Therefore, the result of the judgment is that the first word of the memory cell 405 for replacement is allocated for correcting a defect in the third word, and the result of the judgment is kept in the register.

Next, (iii) when the third bit that is the corresponding bit address of the access-forbidden memory cell 404 is read, data is not stored. Therefore, the result of the judgment is that access (writing and reading) to the third word of the main memory cell 401 is possible, and the result of the judgment is kept in the register.

Finally, (iv) when the memory cell for preventing additional writing 406 in the first word of the memory cell 405 for replacement is read, data is not stored. Therefore, the result of the judgment is that writing operation can be executed to the first word of the memory cell 405 for replacement, and the result of the judgment is kept in the register.

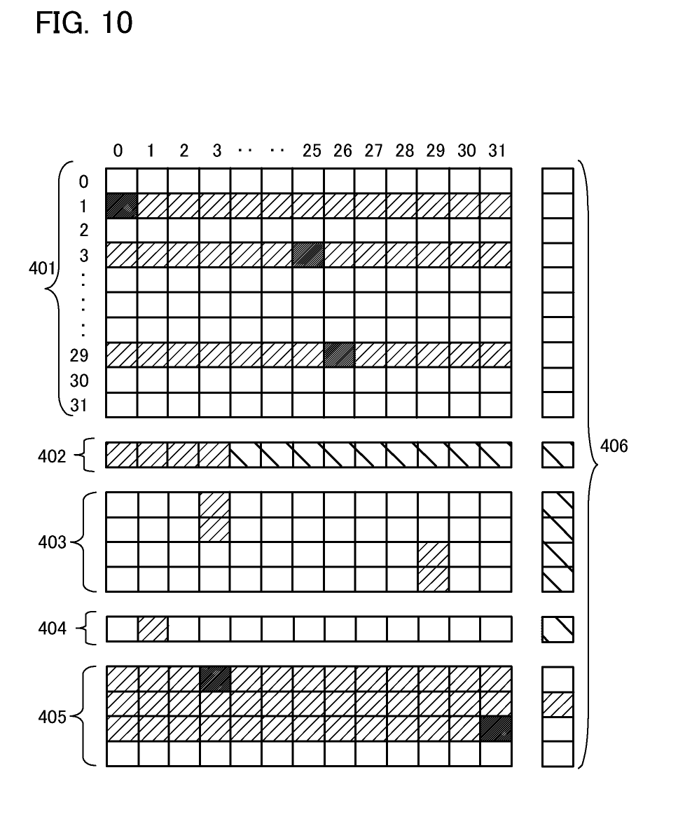

According to the result of the judgment of (i) to (iv), it is determined that an address signal is transmitted to the first word of the memory cell 405 for replacement in order to write data. After that, writing data is executed (see the memory cell 405 for replacement in FIG. 10).

When the data is read from memory cell and the comparison between the read data and the expected value is executed immediately after writing data, the result of the comparison shows the data matches the expected value because writing succeeds.

Therefore, the data is stored in the memory cell for preventing additional writing 406 in the first word of the memory cell 405 for replacement, which is the word address where writing succeeds (see the memory cell for preventing additional writing 406 in FIG. 10).

Next, description is made on the case (8) where the third word is specified by an address signal. Note that FIG. 10 is a memory map when the address signal is received.

In FIG. 10, the result of the judgment of (i), (ii), and (iii) is as the same as that in the case of (7) described above. Since only the result of the judgment of (iv) is different from that in the case of (7), the result of the judgment of (iv) will be described below.

(iv) When the memory cell for preventing additional writing 406 in the first word of the memory cell 405 for replacement is read, the data is stored. Therefore, the result of the judgment is that writing operation cannot be executed to the first word in the memory cell 405 for replacement, and the result of the judgment is kept in the register.

According to the result of the judgment of (i) to (iv), since the function for preventing additional writing is applied to the first word of the memory cell 405 for replacement, writing data is not executed and the operation is finished.

### Embodiment 2

In this embodiment, an example of a method of writing data to memory cells in the semiconductor memory device is described.

In this semiconductor memory device, operation A, operation B, and operation C are alternately executed at most 4 times when data is written to a memory cell: operation A; data is written during a predetermined period (for example, 75.5 μs), operation B; data is read during a predetermined period (for example, 18.9 μs), and operation C; the written data and the read data are compared. Note that hereinafter the data comparison according to operation C is referred to as “verify function,” a series of operations A, B, and C is referred to “verify writing.”

If the results of the verify function do not match each other when the verify writing is repeated 4 times to one memory cell, the data α that the result do not match is kept inside a circuit as information and after that the process proceeds to the next memory cell. On the other hand, if the results of the verify function correspond to each other, the process proceeds to the next memory cell at that time.

If the data α is kept inside a circuit, that is, if the writing is failed when the verify writing to the last memory cell is finished, data is stored in the memory cell for redundant function and the memory cell for redundant judgment to correct a defect. On the other hand, if the data α is not kept inside a circuit, that is, if the writing is finished normally when the verify writing to the last memory cell is finished, data is stored in the memory cell for preventing additional writing to prevent additional writing.

The time for writing data to a memory cell can be shorten with the verify writing.

In addition, the verify writing is very effective for memory cells that can be written only once because an after-writing state is needed to be controlled with high precision.

This embodiment can be freely combined with any of other embodiments.

### Embodiment 3

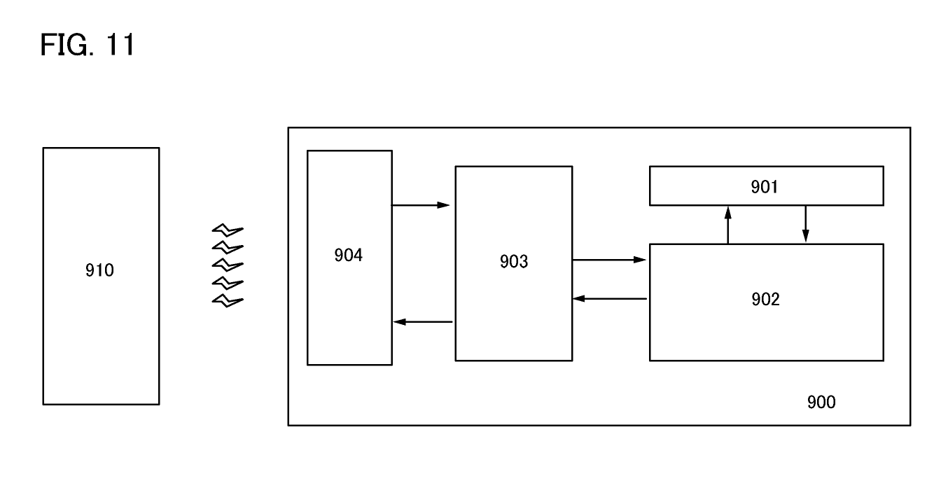

In this embodiment, an example of a structure of a semiconductor device capable of wireless communication is described with reference to FIG. 11. Here, FIG. 11 is a circuit block diagram showing a semiconductor device 900 capable of wireless communication. As shown in FIG. 11, the semiconductor device 900 includes a memory circuit 901, a digital circuit 902, an analog circuit 903, and an antenna circuit 904.

The antenna circuit 904 receives a radio wave (an electromagnetic wave) transmitted from a reader/writer 910 and inputs a signal obtained at that time to the analog circuit 903. The analog circuit 903 demodulates a signal and inputs a demodulated signal to the digital circuit 902. The memory circuit 901 executes writing or reading of data in response to an output from the digital circuit 902.

By applying the semiconductor memory device according to the present invention to the memory circuit 901, a highly reliable semiconductor device which can operate fast can be offered.

The semiconductor device can be applied in a wide field of applications because the semiconductor device has a function of transmitting electronic information stored in the memory circuit 901 to the outside in response to a request for reading receiving from the outside. For example, the semiconductor device storing electronic information can be incorporated with a non-electronic recording medium recording printed information.

This embodiment can be freely combined with any of other embodiments.

### Example 1

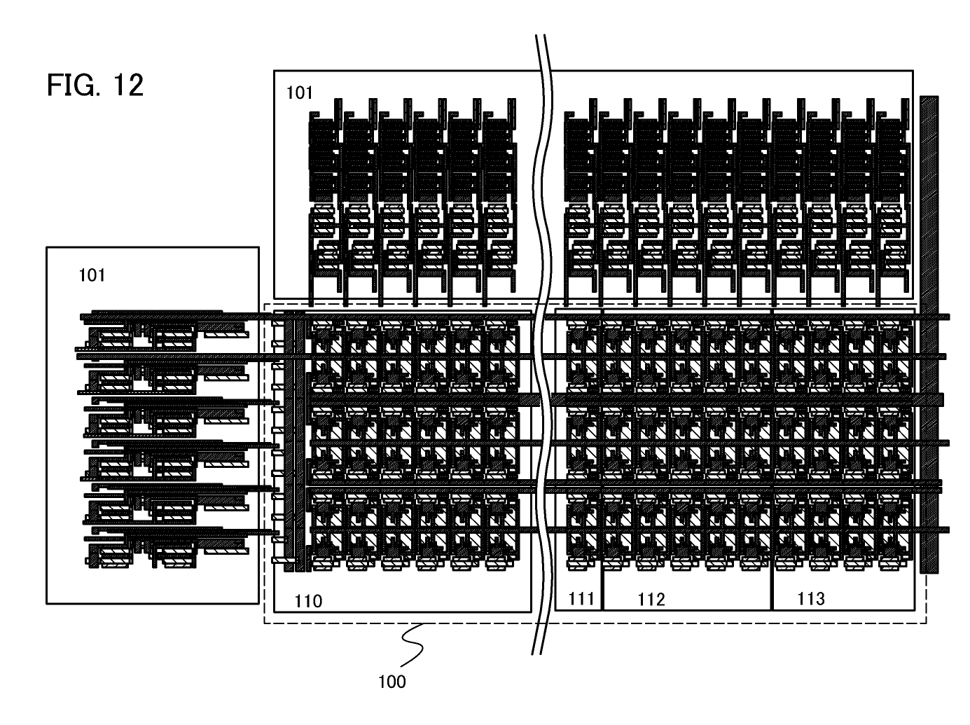

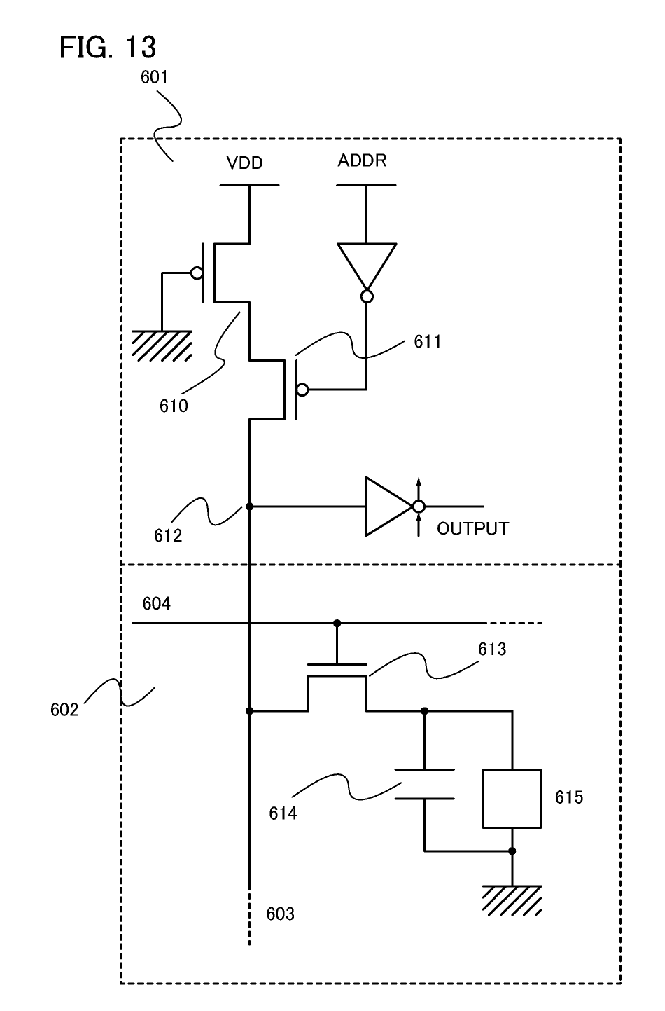

In this example, an example of a mask layout of semiconductor memory device is described with reference to FIG. 12 and FIG. 13.

FIG. 12 shows a mask layout of the semiconductor memory device according to the present invention. The memory cell array 100 and the reading driver 101 which is around memory cell array 100 are shown in FIG. 12.

The memory cell array 100 includes the main memory cell 110 and the spare memory. Note that the spare memory is provided with the memory cell 111 for a redundant function, the memory cell 112 for redundant judgment, and the memory cell 113 for replacement.

FIG. 13 shows a circuit diagram of a memory cell in the spare memory in FIG. 12.

A reading circuit 601 is provided for each bit line 603 and outputs an output in accordance with the element resistance of a memory cell 602 selected by a word line 604 from an OUTPUT. The OUTPUT selects only the output from a bit line 603 selected by a clocked inverter provided in each reading circuit 601.

The output of the OUTPUT is determined by a voltage of a node 612 that is determined by the ratio of X and Y where X is the element resistance and the resistance of a select TFT 613 in the memory cell 602, and Y is the resistance of a comparison TFT 610 and address TFT 611 in the reading circuit 601.

Accordingly, it is necessary to determine the resistance of the selected TFT 613 and the resistance of the comparison TFT 610 so that the resistance X in a short-circuit state<the resistance Y<the resistance X in an off state. Note that, the address TFT may be almost ignored because the address TFT has much smaller resistance than the comparison TFT 610.

In addition, the memory cell 602 is provided with an assistant capacitor 614. When data is written to an element 615, the assistant capacitor 614 accumulates charge through the select TFT 613, supplies charge when the element 615 is short-circuited, and compensates electric power for writing.

This application is based on Japanese Patent Application serial no. 2008-254100 filed with Japan Patent Office on Sep. 30, 2008, the entire contents of which are hereby incorporated by reference.

### EXPLANATION OF REFERENCE

100: memory cell array, 101: reading driver, 102: redundant control circuit portion, 110: main memory cell, 111: memory cell for redundant function, 112: memory cell for redundant judgment, 113: memory cell for replacement, 114: memory cell for preventing additional writing, 120: redundancy controlling circuit, 121: redundancy comparator circuit, 122: redundancy latch circuit, S201-S210: step, S301-S304: step, 401: main memory cell, 402: memory cell for redundant function, 403: memory cell for redundant judgment, 404: access-forbidden memory cell, 405: memory cell for replacement, 406: a memory cell for preventing additional writing, 601: reading circuit, 602: memory cell, 603: bit line, 604: word line, 610: comparison TFT, 611: address TFT, 612: node, 613: select TFT, 614: assistant capacitor, 615: element, 900: semiconductor device, 901: memory circuit, 902: digital circuit, 903: analog circuit, 904: antenna circuit, 910: reader/writer.

1. A semiconductor memory device comprising:
a control circuit;
a reading driver;
a first memory cell array including a plurality of memory cells capable of writing and reading; and
a second memory cell array including a plurality of redundant memory cells,
wherein the second memory cell array has a first region including a first redundant memory cell configured to store the number of times correcting a writing defect and a second region including a second redundant memory cell configured to store an address of a defective memory cell.

2. The semiconductor memory device according to claim 1, further comprising a memory cell for preventing additional writing.

3. The semiconductor memory device according to claim 2, wherein the memory cell includes a nonvolatile memory configured to retain stored data even when the power is turned off.

4. The semiconductor memory device according to claim 1, further comprising a third region including a third redundant memory cell configured to store an access-forbidden address for a word in the first memory cell array.

5. The semiconductor memory device according to claim 1, wherein the semiconductor memory device is selected from the group consisting of a DRAM, an SRAM, a mask ROM, a PROM, an EPROM, an EEPROM, a flash memory, and the like.

6. The semiconductor memory device according to claim 1, wherein the semiconductor memory device is incorporated into a semiconductor device capable of wireless communication such as a RFID, and the like.

7. The semiconductor memory device according to claim 1, further comprising a fourth region including a fourth redundant memory cell for replacing the defective memory cell.

8. A semiconductor memory device comprising:
a redundant control circuit;
a reading driver;
a first memory cell array including a plurality of memory cells capable of writing and reading; and
a second memory cell array including a plurality of redundant memory cells,
wherein the second memory cell array has a first region including a first redundant memory cell configured to store the number of times correcting a writing defect and a second region including a second redundant memory cell configured to store an address of a defective memory cell, and
wherein the redundant control circuit and the reading driver are provided in a periphery of the semiconductor memory device.

9. The semiconductor memory device according to claim 8, further comprising a memory cell for preventing additional writing.

10. The semiconductor memory device according to claim 9, wherein the memory cell includes a nonvolatile memory configured to retain stored data even when the power is turned off.

11. The semiconductor memory device according to claim 8, further comprising a third region including a third redundant memory cell configured to store an access-forbidden address for a word in the first memory cell array.

12. The semiconductor memory device according to claim 8, wherein the semiconductor memory device is selected from the group consisting of a DRAM, an SRAM, a mask ROM, a PROM, an EPROM, an EEPROM, a flash memory, and the like.

13. The semiconductor memory device according to claim 8, wherein the semiconductor memory device is incorporated into a semiconductor device capable of wireless communication such as a RFID, and the like.

14. The semiconductor memory device according to claim 8, further comprising a fourth region including a fourth redundant memory cell for replacing the defective memory cell.

15. A driving method of a semiconductor memory device comprising:
a first memory cell array; and
a second memory cell array including a first region and a second region,
wherein the first region is configured to store a number of times correcting defects,
wherein the second region is configured to replace the defect word in a first memory cell array, the driving method comprising the steps of:
writing data to an access word of the first memory cell array;
judging whether the number of correcting is n-th number or not, when data writing is failed;
writing data to an access word of the second region, the address of the access word is assigned by the data of first region, when the number is not n-th number; and
judging whether the writing to the second region is successful or not.

16. A driving method of a semiconductor memory device according to claim 15, wherein the n-th number corresponds to a word number of the second region.
